(19) United States
(12) Patent Application Publication
(10) Pub. No.: US 2025/0364268 A1
(43) Pub. Date: Nov. 27, 2025

(54) PLASMA PROCESSING METHOD

(71) Applicant: Hitachi High-Tech Corporation, Minato-ku, Tokyo (JP)

(72) Inventors: Miyako TANAHASHI, Tokyo (JP); Kenichi KUWAHARA, Tokyo (JP)

(21) Appl. No.: 18/690,902

(22) PCT Filed: Feb. 15, 2023
(86) PCT No.: PCT/JP2023/005140

§ 371 Date: Mar. 11, 2024

(51) Int. Cl. H01L 21/3213

(52) U.S. Cl. CPC H01L 21/32136

(57) ABSTRACT

A plasma processing method includes: a first step of forming a pattern by irradiating a molybdenum or ruthenium film with plasma generated using an oxygen gas and a halogen gas; after the first step, a second step of forming a protective film containing carbon on a pattern side wall with plasma using a gas containing carbon; a third step of selectively removing the protective film on a pattern bottom portion and oxidizing the molybdenum or ruthenium film on the pattern bottom portion with plasma generated using an oxygen gas; and a fourth step of etching the oxidized molybdenum or ruthenium film with plasma generated using a halogen gas. The second step to the fourth step are repeated until reaching a predetermined depth. The method can further include a step of removing the protective film containing carbon formed on the pattern side wall and an altered layer with plasma containing hydrogen.

### TECHNICAL FIELD

The present disclosure relates to a plasma processing method, and more particularly, to a plasma processing method for a pattern of a wiring material such as molybdenum (Mo) and ruthenium (Ru).

### BACKGROUND ART

For miniaturization and three-dimensionalization of a functional device product such as a semiconductor device, a three-dimensional processing technique for various materials such as gate materials, interlayer films, and metals is important in a dry etching step during semiconductor manufacturing, and a technique of processing a complicated shape by controlling a shape at an atomic layer level is required. In particular, miniaturization proceeds also in a wiring step, an increasing wiring resistance becomes an issue in the future with a copper (Cu) wiring used in the related art, and a use of molybdenum (Mo), ruthenium (Ru), and the like as wiring materials is considered.

As a Mo etching method, NPL 1 proposes a method for etching Mo by several atomic layers per cycle by alternately performing oxygen (O₂) plasma processing and chlorine (Cl₂) plasma processing on a Mo film having no pattern. When a pattern is processed using this method, oxidation proceeds also in a side wall direction of the pattern by the O₂ processing, and oxidized Mo is removed by Cl₂ plasma and is isotropically etched, and thus it is difficult to process the pattern in a vertical direction.

Further, as a Mo pattern etching method, there is reported a method for performing plasma etching using a mixed gas containing halogen and oxygen, such as a mixed gas containing a chlorine gas (Cl₂) and an oxygen gas (O₂) or a mixed gas containing a hydrogen bromide (HBr) and an oxygen gas (O₂). However, as shown in (FIG. 2A, in a device structure having a Mo pattern 102, which is an etching target material formed on a substrate 101, and masks 103 formed on the Mo pattern 102, when the plasma etching is performed using a mixed gas containing halogen and oxygen, side etching is likely to be performed in a side wall direction of the pattern 102, and thus it is difficult to process the pattern to have a vertical cross-sectional shape. Further, since Mo is easily oxidized, a surface may be easily oxidized during etching or after etching and a wiring resistance may be increased. In order to prevent the side wall of the Mo pattern 102 from being etched, as shown in FIG. 2B, NPL 2 proposes a method in which a thin SiO₂ film 104 is formed as a side wall protective film of the Mo pattern 102 formed on the substrate 101 by atomic layer deposition (ALD) in the middle of processing of the Mo pattern 102, and then the Mo pattern 102 is processed by plasma generated using a mixed gas of Cl₂ and O₂.

### CITATION LIST

### Non Patent Literature

NPL 1: Yebin Lee, and 3 others, Low-temperature plasma atomic layer etching of molybdenum via sequential oxidation and chlorination, Journal of Vacuum Science & Technology A 40, 022602 (2022); https://doi.org/10.1116/6.0001603
NPL 2: Stefan Decoster, and 7 others, Patterning challenges for directmetal etch of ruthenium and molybdenum at 32 nm metal pitch and below, Journal of Vacuum Science & Technology B 40, 032802 (2022); https://doi.org/10.1116/6.0001791

### SUMMARY OF INVENTION

### Technical Problem

As described above, in order to vertically process a fine pattern of Mo or Ru, a technique of preventing etching in a side wall direction and performing processing is important. In etching using a mixed gas of Cl₂ or halogen and O₂ as in the related art, the etching may proceed in the side wall direction, resulting in poor anisotropy and inability to perform vertical processing. In addition, since the Mo or Ru surface is fairly easily oxidized, a molybdenum oxide (MoOₓ) or a ruthenium oxide (RuOₓ) remaining after processing may increase the wiring resistance.

In NPL 1, O₂ plasma processing and Cl₂ plasma processing are alternately performed on a Mo film having no pattern, so that the etching is performed by several atomic layers per cycle. However, when the pattern is processed using this method, since the pattern side wall is easily oxidized by the O₂ processing, and the oxidized Mo is removed by the Cl₂ plasma processing, the etching also occurs in the side wall direction of the pattern, making it difficult to process the pattern in the vertical direction.

In NPL 2, in order to prevent etching in the side wall direction of the pattern, the etching is interrupted in the middle of pattern processing, and the thin silicon oxide film (SiO₂ film) 104 is formed on a pattern surface including the side wall of the pattern 102. Thereafter, the SiO₂ film 104 is used as a protective film for preventing the etching in the side wall direction, and Mo etching is performed until reaching a desired depth.

However, in this method, it is necessary to remove SiO₂ of the protective film 104 after processing, but it is difficult to remove only SiO₂ of the protective film 104 without etching Mo on the side wall of the Mo pattern 102 which is a fine pattern. In addition, in the step of removing SiO₂ of the protective film 104, the Mo surface is oxidized, or a residue of the protective film 104 or a reaction product remains on groove bottoms 201 of grooves 200 between the Mo patterns 102, which may cause a failure of the device or an increase in wiring resistance.

An object of the present disclosure is to perform vertical processing while preventing side etching during Mo processing by forming a side wall protective film from a material that can be easily removed after processing. Another object of the invention is to provide a plasma processing method for etching Mo at a uniform etch rate within a wafer surface and performing etching efficiently by performing both removal of an unnecessary protective film formed on a groove bottom and performing Mo etching processing in a Mo vertical processing step. Further, another object of the invention is to remove the side wall protective film without scraping the side wall of the Mo pattern after processing, and to remove residual impurities such as oxides formed on a Mo surface to form a Mo pattern without defects or damage.

### Solution to Problem

In a plasma processing method for forming a pattern by irradiating, with plasma generated using a gas containing oxygen and a gas containing halogen, a pattern of a molybdenum (Mo) film (or a molybdenum-containing film) or a ruthenium (Ru) film (or a ruthenium-containing film), which is an etching target material formed on a wafer placed on a stage, the method includes: a first step of forming a pattern by irradiating the Mo film or the Ru film with plasma generated using a mixed gas of the gas containing oxygen (O₂) and the gas containing halogen; a second step of, after the first step, forming a protective film containing C on a pattern side wall with plasma using a gas containing carbon (C); a third step of, after the second step, selectively removing the protective film on a pattern bottom portion with respect to the protective film on the pattern side wall formed in the second step and oxidizing the Mo film or Ru film on the pattern bottom portion with plasma generated using a gas containing oxygen (O); and a fourth step of, after the third step, generating plasma using a gas containing a halogen gas and etching the Mo film or the Ru film oxidized in the third step. The second step to the fourth step are repeated until reaching a predetermined depth.

The plasma processing method may further include a fifth step of removing the protective film containing C formed in the second step and an altered layer formed in the pattern in the third step and the fourth step using plasma containing hydrogen (H).

### Advantageous Effects of Invention

By forming a protective film containing C on a pattern side wall and etching a pattern bottom portion, it is possible to process the pattern in a vertical direction. In addition, by oxidizing and removing the protective film containing unnecessary C attached to the pattern bottom portion and oxidizing a Mo film or a Ru film on the pattern bottom portion, the Mo film or the Ru film can be efficiently etched at a uniform etch rate within a wafer surface. Further, after the etching is performed until reaching a desired depth, the etching is performed with plasma containing hydrogen (H₂), so that the protective film containing C and an etching residue on the pattern side wall can be removed without etching the Mo film or the Ru film on the side wall.

### BRIEF DESCRIPTION OF DRAWINGS

FIG. 1 is a diagram showing an example of a process flow of a plasma processing method according to the present disclosure.

FIGS. 2A and 2B are diagrams showing problems in a method in the related art, where FIG. 2A is a diagram showing side etching in a side wall direction of a pattern 102, and FIG. 2B is a diagram showing a state in which a side wall protective film for preventing the side etching is formed in the side wall direction of the pattern 102.

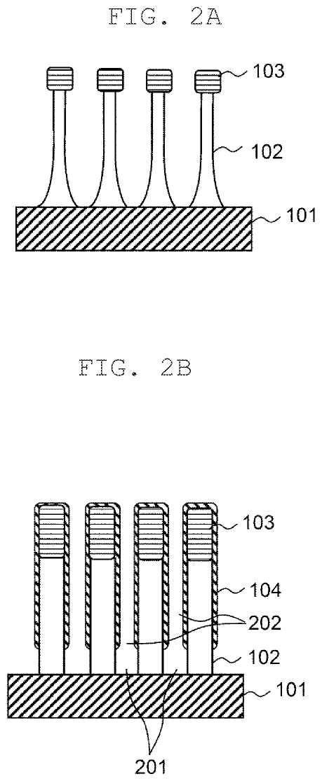

FIG. 3 is a diagram showing an example of an apparatus for performing the plasma processing method according to the present disclosure.

FIG. 4 shows pattern cross-sectional views showing an example of a process flow of the plasma processing method according to the embodiment.

FIG. 5 is a diagram of an example of a protective film removing method in an oxidation processing step according to the embodiment.

FIGS. 6A-6C are diagrams of an example of the oxidation processing step according to the embodiment, where FIG. 6A shows dependency of an etch rate on an oxidation processing time, FIG. 6B shows dependency of a saturated etch rate (ER1) on bias power of oxidation processing (step S3), and FIG. 6C shows dependency of an oxidation processing time (T), which is until etching in a case in which a C-containing protective film 105 is formed is started, on the bias power of the oxidation processing (step S3).

FIGS. 7A and 7B are diagrams of an example of dependency of the etch rate on etching step conditions according to the embodiment, where FIG. 7A shows dependency of the etch rate on a Cl₂ processing time, and FIG. 7B shows dependency of the etch rate on bias power of Cl₂ processing.

FIG. 8 is a diagram showing dependency of an etching amount on the number of cycles when etching is performed using the embodiment.

FIG. 9 is a diagram of an example of a protective film removing step according to the embodiment.

FIG. 10 is a diagram showing another example of a pattern etched using the embodiment.

### DESCRIPTION OF EMBODIMENTS

Hereinafter, an embodiment of the present disclosure will be described in detail with reference to the drawings. In all the drawings, components having the same functions are denoted by the same reference numerals, and repeated description thereof is omitted.

### EMBODIMENT

In an etching apparatus 30 according to the embodiment, for example, a protective film containing carbon (C) is formed on a side wall surface of a fine pattern of a wiring material containing molybdenum (Mo) or ruthenium (Ru) formed on a wafer which is a semiconductor substrate made of single crystal silicon placed on a stage, and a Mo film or a Ru film which is an etching target material of a bottom portion of the pattern is etched and removed. Further, after the etching, the protective film remaining in the pattern, an oxidizing component on Mo or Ru, and a residue such as a reaction product due to the etching are removed by plasma. In the embodiment, although Mo or Ru is used as the etching target material, processing same as in the embodiment can be performed using molybdenum-containing materials (or molybdenum-containing films) or ruthenium-containing materials (or ruthenium-containing films).

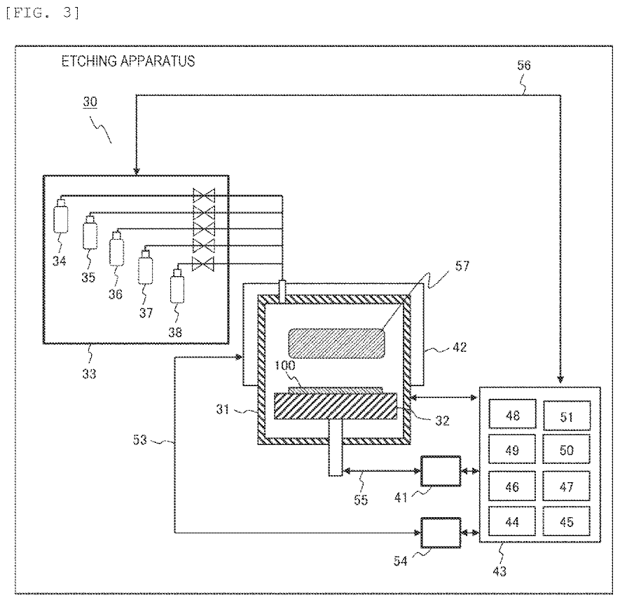

FIG. 3 shows an overall configuration of an example of the plasma processing apparatus 30 used in the embodiment. The etching apparatus 30 as the plasma processing apparatus 30 includes a processing chamber 31, a wafer stage 32 on which a wafer is placed, a gas supply unit 33, a bias power supply 41, a radio frequency application unit 42, and an apparatus control unit 43. The apparatus control unit 43 includes an optical system control unit (not shown), a gas control unit 44, an exhaust system control unit 45, a radio frequency control unit 46, a bias control unit 47, a protective film forming step control unit 48, a determination unit 49, a storage unit 51, and functional blocks such as a clock (not shown). Each functional block constituting the apparatus control unit 43 can be implemented by one personal computer (PC). The apparatus control unit 43 includes the determination unit 49 and a database storage unit 50, and can determine whether desired processing is completed in the determination unit 49 by referring to the database 50 with a signal transmitted from the optical system control unit.

The etching apparatus 30 is provided with the wafer stage 32 provided in the processing chamber 31 and the gas supply unit 33 including a gas cylinder and a valve. Based on a control signal 56 from the apparatus control unit 43, an etching gas 34, a protective film forming gas 35, a film quality control gas 36, an etching gas 37, and a protective film removing gas 38 are supplied to the processing chamber 31 according to a processing step.

A processing gas supplied to the processing chamber 31 is decomposed into plasma 57 in the processing chamber 31 by radio frequency power 53 applied from a radio frequency power supply 54 controlled by the apparatus control unit 43 to the radio frequency application unit 42. In addition, a pressure in the processing chamber 31 can be kept constant in a state in which a predetermined flow rate of the processing gas flows through a variable conductance valve (not shown) and a vacuum pump (not shown) connected to the processing chamber 31. Radicals generated by decomposition into the plasma 57 in the processing chamber 31 are diffused in the processing chamber 31 and emitted onto a surface of a wafer 100 placed on the wafer stage 32. Ions generated by the plasma 57 are accelerated by a bias voltage 55 applied to the wafer stage 32 from the bias power supply 41 controlled by the bias control unit 47 and emitted onto the surface of the wafer 100.

A processing state of the wafer 100 can be determined by the determination unit 49 by obtaining a spectrum of light emitted from a light source (not shown) and reflected by the wafer 100 or a spectrum of light generated by the plasma 57. In the control unit 43, a reflection spectrum and an emission spectrum are stored as reference data in the database 50 in advance, and are determined by comparison with the reference data. That is, the plasma processing apparatus 30 has a function for observing a pattern shape (the determination unit 49 that determines a spectrum of light emitted from a light source and reflected by the wafer 100 or a spectrum of light generated by the plasma 57, the database 50 in which the reflection spectrum and the emission spectrum are used as the reference data in advance, or the like), and is implemented to be able to adjust process conditions such as etching conditions (a substrate temperature, a flow rate of a gas to be used, a bias voltage, and a processing time such as an etching time (an oxidation time)) to obtain a desired pattern shape or a desired pattern dimension from a first step to a fourth step to be described later.

As an embodiment of an etching method in the embodiment, a method for selectively forming a protective film containing carbon (C) with respect to materials of a pattern of a wiring material containing Mo or Ru in the processing chamber 31 and then securing etching resistance by modifying the protective film containing carbon (C) and a method for processing an etching target material such as Mo or Ru at a high selectivity using the modified protective film as a mask will be described.

In the etching apparatus 30 according to the embodiment, the protective film containing carbon (C) is formed on the side wall surface of a fine pattern of a wiring material containing Mo or Ru formed on the wafer 100, and Mo or Ru, which is an etching target material of a bottom portion of the pattern, is etched and removed by plasma containing halogen. Further, after the etching, the protective film remaining on the pattern, the oxidizing component on Mo or Ru, and the residue such as a reaction product (altered layer) due to the etching are removed by emitting plasma containing hydrogen (H) thereon.

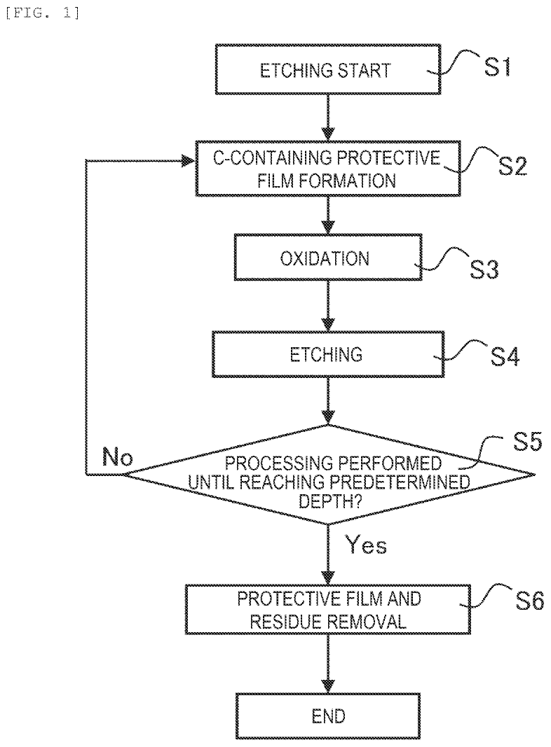

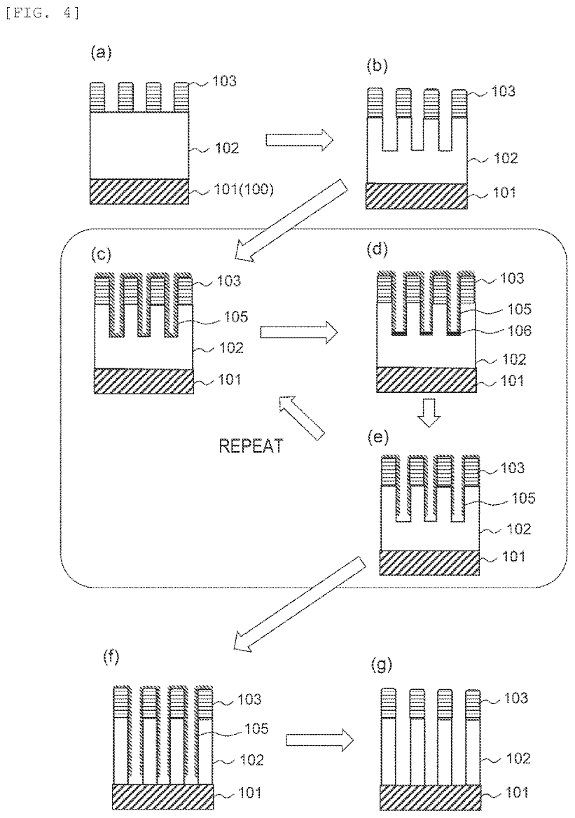

FIG. 1 is a diagram showing an example of a process flow of a plasma processing method according to the embodiment. FIG. 4 is an example of pattern cross-sectional views showing a process flow of a plasma processing method according to the embodiment. In the embodiment, as shown in (a) of FIG. 4, a method for vertically processing an etching target material 102 containing Mo or Ru formed on a surface of the substrate 101 using the mask pattern 103 as a mask will be described based on the flow of FIG. 1. In FIG. 4, the substrate 101 corresponds to the wafer 100. In the embodiment, as an example, a silicon nitride film (SiN) is used as a material of the mask pattern 103, and Mo is used as a material of the etching target material (etching target pattern) 102. The material of the mask pattern 103 may be a silicon oxide film (SiO₂), a silicon nitride film (SiN), a silicon carbide (SiC: silicon carbide), a material containing oxygen (O), nitrogen (N), and carbon (C) in addition to Si, a material containing titanium (Ti) such as titanium nitride (TiN: titanite) and titanium dioxide (TiO₂), a material containing aluminum (Al) or tantalum (Ta) such as aluminum oxide (Al₂O₃) and tantalum nitride (TaN), or a material containing carbon (C).

First, the wafer 100 is introduced onto the wafer stage 32 in the processing chamber 31, and a step of etching the etching target material 102 with respect to a pattern formed on the wafer 100 is started (step S1: etching start step, first step). The etching gas 34 is supplied to the processing chamber 31 at a predetermined flow rate based on the control signal 56 from the apparatus control unit 43. The supplied etching gas 34 becomes the plasma 57 by the radio frequency power 53 applied to the radio frequency application unit 42, and generates radicals and ions for etching the etching target material 102. The radicals and ions generated by the plasma 57 reach the surface of the wafer 100, and as shown in (b) of FIG. 4, etching of the etching target material 102 containing Mo or Ru is started using the mask patterns 103 as the masks. As the etching gas 34, for example, a mixed gas of an O₂ gas and a halogen gas such as a chlorine gas (Cl₂), a hydrogen bromide gas (HBr), a nitrogen trifluoride gas (NF₃), or a sulfur hexafluoride gas (SF₆) can be used. Alternatively, as the etching gas 34, a mixed gas of an O₂ gas and a fluorocarbon gas such as a tetrafluoromethane gas (CF₄) or a trifluoromethane gas (CHF₃) and a hydrofluorocarbon gas can be used. Ions generated from the etching gas 34 are accelerated by the bias voltage 55 applied to the wafer stage 32 from the bias power supply 41 controlled by the bias control unit 47 and emitted onto the surface of the wafer 100.

Here, the etching in step S1 is required to be stopped before the etching proceeds in a side wall direction of the etching target material 102. Optimum values of the etching time, the bias voltage, and the substrate temperature in step S1 are preferably obtained in advance, whereas a pattern dimension and a depth of a pattern of a groove (concave portion) formed by etching the etching target material 102 may be determined by the determination unit 49 by obtaining a spectrum of light emitted from a light source installed in the etching apparatus 30 and reflected by the wafer 100 or a reflection spectrum of light generated by the plasma 57. Here, a horizontal direction is a direction horizontal to the surface of the wafer 100 (or the substrate 101), a vertical direction is a direction perpendicular to the horizontal direction, and is a direction perpendicular to the surface of the wafer 100 (or the substrate 101). A pattern dimension means an interval between the grooves (concave portions) in the horizontal direction, and a pattern depth means a depth of the groove (concave portion) in the vertical direction. When the pattern dimension of the pattern of the groove (concave portion) of the etching target material 102 does not fall within a predetermined range, for example, when the pattern dimension is larger than a predetermined dimension, the pattern dimension can be reduced to fall within the predetermined range by performing etching while increasing the substrate temperature. When the pattern dimension is smaller than the predetermined dimension, the pattern dimension can be increased to fall within the predetermined range by performing etching while lowering the substrate temperature. When a dimension of the initial mask pattern 103 has a distribution within the surface of the wafer 100, the pattern of the groove (concave portion) having a uniform dimension can be formed by changing the substrate temperature according to a position in the wafer stage 32 so that the pattern dimension of the pattern of the groove (concave portion) formed by etching is within the predetermined range and uniform.

Next, before the etching proceeds in the side wall direction of the etching target material 102 during the etching in step S1, as shown in (c) of FIG. 4, the protective film 105 containing carbon (C) is formed on a surface including a pattern side wall of the pattern of the groove (concave portion) of the etching target material 102 (step S2: C-containing protective film forming step, second step). Based on a control signal from the protective film forming step control unit 48, the protective film forming gas 35 is supplied to the processing chamber 31 at a predetermined flow rate, and becomes the plasma 57 by the radio frequency power 53 applied to the radio frequency application unit 42, thereby generating radicals and ions. The radicals and ions generated from the protective film forming gas 35 have a property of bonding with or adhering to and depositing the material of the mask pattern 103 and the etching target material 102, and the radicals and ions generated by the plasma 57 reach the surface of the wafer 100, and form the protective film 105 containing C on an upper surface of the mask pattern 103 and the pattern side wall (side wall surface) of the etching target material 102. The protective film forming step control unit 48 can control a film thickness and a film quality of the protective film 105 by setting and adjusting a flow rate of the protective film forming gas 35, the radio frequency power 53 applied to the radio frequency application unit 42, the substrate temperature, a plasma irradiation time, and the like. As the protective film forming gas 35, for example, a gas containing carbon (C) such as a methane gas (CH₄), a tetrafluoromethane gas (CF₄), a trifluoromethane gas (CHF₃), a fluoromethane gas (CH₃F), a perfluorocyclobutane gas (C₄F₈), a carbon dioxide gas (CO₂), and a carbon monoxide gas (CO), or a mixed gas of the gas containing carbon (C) and an argon gas (Ar), a helium gas (He), an O₂ gas, a CO₂ gas, a CO gas, a nitrogen gas (N₂), and a hydrogen gas (H₂) can be used. The film thickness of the protective film 105 can be adjusted by the plasma irradiation time, a gas flow rate of the protective film forming gas 35, the substrate temperature, and the like. Alternatively, the film thickness of the protective film 105 can be adjusted by adjusting a degree of dissociation of plasma by the radio frequency power 53 applied to the radio frequency application unit 42 to adjust reactivity between generated radicals and ions and a material surface. After formation of the protective film 105, plasma generated by further introducing a gas such as an Ar gas, a He gas, a N₂ gas, or a H₂ gas may be emitted to the pattern of the groove (concave portion) to smooth a shape of the protective film 105 and reduce roughness of the pattern of the groove (concave portion) or roughness of the surface of the protective film.

After the protective film 105 containing C is formed in step S2, oxidation processing is performed (step S3: oxidation processing step, third step), and as shown in (d) of FIG. 4, removal of the unnecessary C-containing protective film 105 formed on a pattern bottom surface (or a pattern bottom portion) of the groove (concave portion) and oxidation processing of a Mo surface of the etching target material 102 of the pattern bottom surface are performed. After the oxidation of Mo on the pattern bottom surface is performed, halogen-containing plasma processing is performed in the next step S4, whereby oxidized Mo (Mo oxide film) 106 is selectively etched to promote the Mo etching, and Mo on the pattern bottom surface can be etched with good controllability.

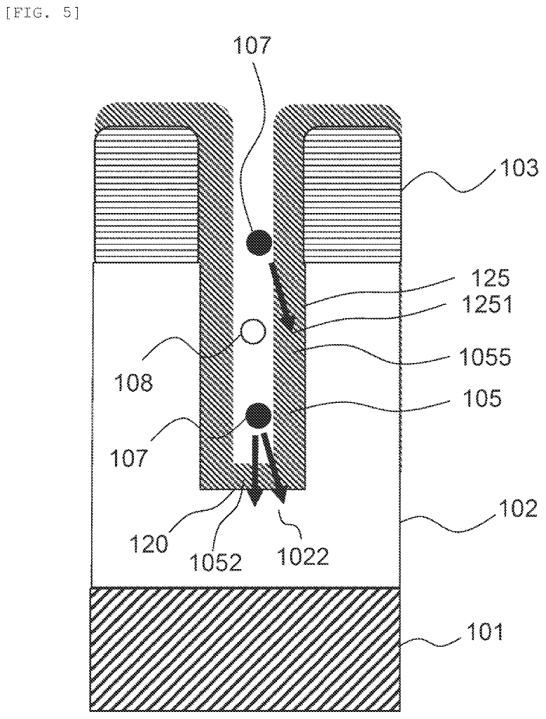

First, the film quality control gas 36 is supplied to the processing chamber 31 at a predetermined flow rate based on the control signal 56 from the apparatus control unit 43. As the film quality control gas 36, a mixed gas of a gas containing oxygen (O) such as an oxygen gas (O₂), a carbon dioxide gas (CO₂), and a sulfur dioxide gas (SO₂) and a rare gas such as Ar and He is supplied to the processing chamber 31. The supplied gas becomes plasma by the radio frequency power 53 applied to the radio frequency application unit 42, is decomposed into radicals, ions, and the like, and is emitted onto the surface of the wafer 100. Here, FIG. 5 shows a diagram of an example of a protective film removing method in the oxidation processing step (S3). Ions 107 such as Ar generated from the film quality control gas 36 are accelerated by the bias voltage 55 applied to the wafer stage 32 from the bias power supply 41 controlled by the bias control unit 47, and emitted onto the surface of the wafer 100. As an example, a case is shown in which the protective film 105 is formed with the protective film 105 having the same thickness on the upper surface and the side wall of the mask 103 and the bottom surface and the side wall of the groove (concave portion) of the etching target material 102. Carbon (C) in the protective film 105 reacts with oxygen radicals 108 generated from the film quality control gas 36 to generate CO₂ and volatilize. At this time, when the ions 107 have energy capable of passing through the protective film 105 (1052) of the pattern bottom surface 120 of the groove (concave portion), the protective film 105 (1052) containing C quickly reacts with the oxygen radicals 108, and the protective film 105 (1052) of the pattern bottom surface 120 can be removed. When the ions 107 have energy capable of passing through the protective film 105 (1052) of the pattern bottom surface 120, the oxygen radicals 108 reach Mo (1022) of the etching target material 102 below the protective film 105 (1052), and Mo (1022) below the protective film 105 (1052) is easily oxidized (the oxidized Mo (Mo oxide film) 106 in (d) of FIG. 4). On the other hand, when the ions 107 are emitted onto a pattern side wall 125 of the groove (concave portion) of the etching target material 102, the ions 107 are emitted at a low incident angle with respect to the protective film 105 (1055) deposited on the pattern side wall 125, so that the ions 107 can only penetrate up to a surface region 1251 of the protective film 105 (1055), and it takes more time to remove the protective film 105 (1055) on the pattern side wall 125 of the etching target material 102 than to remove the protective film 105 (1052) on the pattern bottom surface 120. The protective film 105 (1055) on the pattern side wall 125 can prevent the pattern side wall 125 of the etching target material 102 from being oxidized. That is, it is preferable that the bias voltage 55 with which ions having energy that passes through the protective film 1052 formed on the pattern bottom portion 120 but does not pass through the protective film 1055 on the pattern side wall 125 can be emitted is applied to the wafer stage 32 from the bias power supply 41 controlled by the bias control unit 47. Therefore, by adjusting the energy of the ions generated from the film quality control gas 36, the protective film 105 (1052) on the pattern bottom surface 120 can be removed while leaving the protective film 105 (1055) on the pattern side wall 125, and the etching target material 102 (1022) on the pattern bottom surface 120 can be oxidized.

After the protective film 105 (1052) on the pattern bottom surface 120 is removed, the oxide film (the oxidized Mo (Mo oxide film) 106 in (d) of FIG. 4) of the etching target material 102 (1022) formed on the pattern bottom surface 120 is etched using plasma containing halogen (step S4: etching step, fourth step).

First, the etching gas 37 is supplied to the processing chamber 31 at a predetermined flow rate based on the control signal 56 from the apparatus control unit 43. As the etching gas 37, a mixed gas containing halogen, fluorocarbon, and hydrofluorocarbon gases such as Cl₂, HBr, CF₄, CHF₃, NF₃, and SF₆ is supplied to the processing chamber 31. The supplied gas becomes plasma by the radio frequency power 53 applied to the radio frequency application unit 42, is decomposed into radicals, ions, and the like, and is emitted onto the surface of the wafer 100, and as shown in (e) of FIG. 4, the oxidizing component (the Mo oxide film 106: (d) of FIG. 4) of the etching target material 102 (1022) oxidized on the pattern bottom surface 120 is preferentially etched. By accelerating the ions generated from the etching gas 37 by the bias voltage 55 applied to the wafer stage 32 from the bias power supply 41 controlled by the bias control unit 47, the oxidized etching target material 102 (the Mo oxide film 106: (d) of FIG. 4) on the pattern bottom surface 120 can be etched more efficiently. Meanwhile, since the etching of the etching target material 102 on the pattern side wall 125 is prevented by the C-containing protective film 105, the etching of the etching target material 102 on the pattern side wall 125 in a lateral direction can be prevented, and the etching target material 102 on the pattern bottom surface 120 can be etched in the vertical direction.

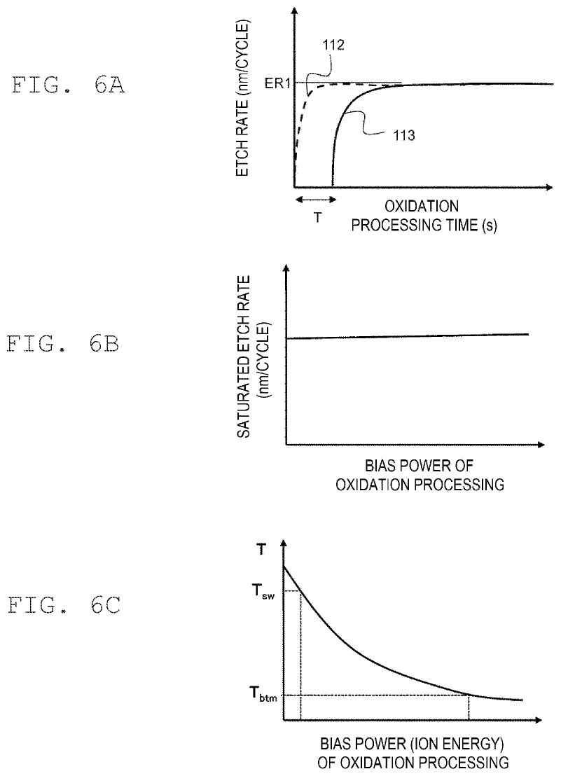

FIGS. 6A-6C are diagrams of the oxidation processing step (S3) in the case of performing the protective film formation (step S2), the oxidation processing (step S3), and the etching (step S4). FIG. 6A shows dependency of the etch rate on the oxidation processing time. The dependency of the etch rate on the oxidation processing time in the case in which the C-containing protective film 105 is not formed on the etching target material 102 is indicated by 112, and the dependency of the etch rate on the oxidation processing time in the case in which the C-containing protective film 105 is formed on the etching target material 102 is indicated by 113. When the C-containing protective film 105 is not formed, if the oxidation processing (step S3) is performed, the etch rate rapidly increases and is saturated at a certain etch rate (ER1). As an example, when Mo was oxidized at a pressure of 0.2 Pa, the etch rate was saturated at 4 nm/cycle. It is found that, when the C-containing protective film 105 is formed on the etching target material 102, oxidation for a certain oxidation processing time (T) or longer is required for etching. This indicates that the oxidation is prevented by the C-containing protective film 105 and that it takes time to remove the C-containing protective film 105 by the oxidation. Even when the C-containing protective film 105 is formed, if the oxidation processing time is increased, the etch rate (ER1) is saturated, which is substantially the same as that when the C-containing protective film 105 is not formed, indicating that the C-containing protective film 105 is removed by the oxidation.

(FIG. 6B shows dependency of the saturated etch rate (ER1) on the bias power of the oxidation processing (step S3). It is found that Mo, which is the etching target material 102, is a material which is easily oxidized, and when the oxidation processing (step S3) is performed using plasma, since a thickness of the Mo oxide film does not greatly depend on the bias power, the saturated etch rate hardly depends on the bias power of the oxidation processing (step S3). For example, even when an O₂ processing time is increased from 1 second to 10 seconds, the etch rate is constant at about 4 nm/cycle, and even when the bias power of the O₂ processing is increased from 0 W to 50 W, the etch rate is almost constant at about 4 nm/cycle.

FIG. 6C shows dependency of the oxidation processing time (T), which is until the etching in the case in which the C-containing protective film 105 is formed is started, on the bias power of the oxidation processing (step S3). It is found that the time required to remove the protective film 105 greatly depends on the bias power of the oxidation processing (step S3), that is, the energy of the ions. When a line pattern as shown in FIG. 4 is etched, the ions are incident on the protective film 105 (1052) on the pattern bottom surface 120 from the vertical direction, whereas the ions are incident on the protective film 105 (1055) on the pattern side wall 125 at a low angle, and thus the energy in the vertical direction with respect to the protective film 105 (1055) on the pattern side wall 125 is small, and a time (T_{sw}) required to remove the protective film 105 (1055) on the pattern side wall 125 is longer than a time (T_{btm}) required to remove the protective film 105 (1052) on the pattern bottom surface 120 (T_{sw}>T_{btm}). Therefore, when the oxidation processing time of the oxidation processing (step S3) is set between T_{btm} and T_{sw}, the protective film 105 (1055) on the pattern side wall 125 is left and the protective film 105 (1052) on the pattern bottom surface 120 can be removed. By removing the protective film 105 (1052) on the pattern bottom surface 120, the etching target material 102 (1022) only on the pattern bottom surface 120 can be oxidized.

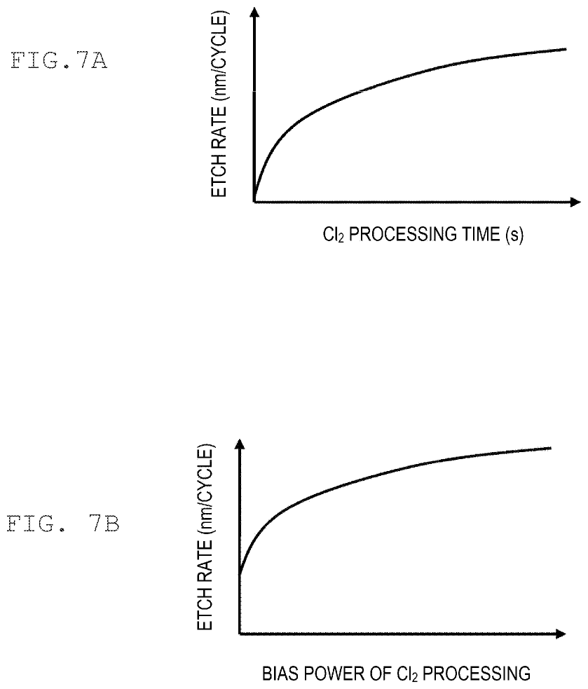

FIGS. 7A and 7B show a diagram of an example of dependency of the etch rate on etching step conditions in the embodiment. When Cl₂ is used as the halogen gas in the etching step (S4), FIG. 7A shows dependency of the etch rate on a Cl₂ processing time, and FIG. 7B shows dependency of the etch rate on the bias power of the Cl₂ processing. As the Cl₂ processing time becomes longer and as the bias power of the Cl₂ processing increases, the etch rate tends to gradually increase. For example, when the Cl₂ processing time is increased from 3 seconds to 20 seconds, the etch rate is increased from 3 nm/cycle to 6 nm/cycle, and when the bias power of the Cl₂ processing is increased from 0 W to 50 W, the etch rate is increased from 3 nm/cycle to 5 to 6 nm/cycle.

Here, in the protective film forming step (S2) of forming the C-containing protective film 105 on the pattern side wall 125 and the oxidation processing step (S3) of oxidizing the C-containing protective film 105 on the pattern bottom surface (bottom portion) 120, by oxidizing and removing the protective film 105 under the pattern side wall 125, a lower portion of the pattern side wall 125 can be etched in the lateral direction to make the dimension of the pattern uniform within the surface of the wafer 100. Optimum values of the etching time (oxidation time), the bias voltage, and the substrate temperature in the oxidation processing step S3 are preferably obtained in advance, and a pattern shape may be observed by determining, by the determination unit 49, a pattern dimension and a depth by obtaining a spectrum of light emitted from a light source installed in the etching apparatus 30 and reflected by the wafer 100 or a reflection spectrum of light generated by the plasma 57. When the pattern dimension does not fall within a predetermined range, for example, when the pattern dimension is larger than a predetermined dimension, the pattern dimension can be reduced to fall within the predetermined range by performing the oxidation processing step (S3) and the etching step (S4) while increasing the substrate temperature. For example, when the substrate temperature is 10° C., the etch rate is 2 nm/cycle, whereas when the substrate temperature is increased to 80° C., the etch rate increases to 5 nm/cycle. When the pattern dimension is smaller than the predetermined dimension, the pattern dimension can be increased to fall within the predetermined range by performing the oxidation processing step (S3) and the etching step (S4) while lowering the substrate temperature. Alternatively, by increasing the substrate temperature to reduce the thickness of the protective film 105 in the protective film forming step (S2), the pattern dimension can be reduced to fall within the predetermined range. On the other hand, when the pattern dimension is increased to fall within the predetermined range, the thickness of the protective film 105 can be increased by lowering the substrate temperature in the protective film forming step (S2). By performing the etching while changing the substrate temperature within the wafer surface, the pattern dimension can be precisely adjusted. That is, in the oxidation processing step (S3), an in-plane temperature distribution of the wafer stage 32 is adjusted, the substrate temperature of the wafer 100 is adjusted, and the pattern dimension within the surface of the wafer 100 can be made uniform. Alternatively, it is preferable to provide a step of observing the pattern shape and adjusting process conditions (a substrate temperature, a flow rate of a gas to be used, a bias voltage, and a processing time such as an etching time (oxidation time)) such as etching conditions of the etching start step (S1), the protective film forming step (S2), the oxidation processing step (S3), and the etching step (S4) to obtain a desired pattern dimension.

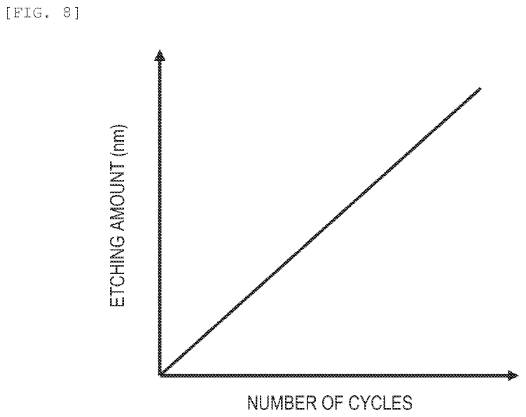

Here, while performing the etching processing (S4), the film thickness, the pattern dimension, and an etching depth of the protective film 105 are measured by an optical system, one cycle of the protective film forming step (S2), the oxidation processing step (S3), and the etching step (S4) is repeated by a predetermined number of cycles until a pattern depth of the etching target material 102 on the wafer 100 is etched to a desired etching depth, and when a predetermined number of times of etching processing or a desired etching depth is reached (Yes), the etching is completed (step S5). Here, cycle processing refers to processing in which one cycle of the protective film forming step (S2), the oxidation processing step (S3), and the etching step (S4) is repeated a predetermined number of cycles. FIG. 8 shows dependency of an etching amount on the number of cycles when the cycle processing shown in the embodiment is used. It is confirmed that the etching proceeds to a certain depth per cycle.

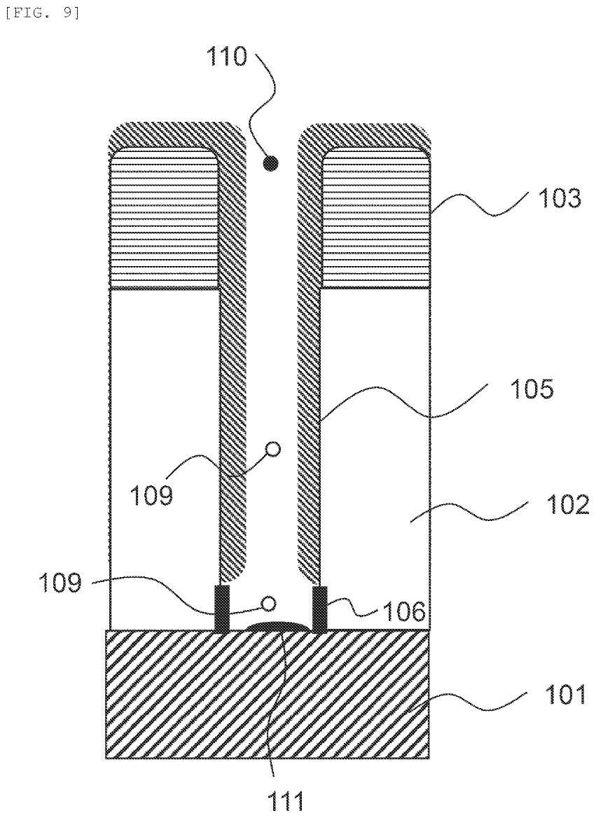

As shown in (f) of FIG. 4, after the etching is performed until reaching a predetermined depth, removal of the C-containing protective film 105 is performed (step S6: protective film and residue removing step, fifth step). FIG. 9 shows a schematic view of a pattern cross section after the etching is performed to the predetermined depth. The C-containing protective film 105, the oxide film 106 of the oxidized etching target material 102, and an etching residue 111 are formed on the pattern of the etching target material 102. For example, when the etching target material 102 is a wiring material, the C-containing protective film 105 remaining on the etching target material 102, the oxide film 106 of the oxidized etching target material 102, and the etching residue 111 mix into the wiring material as impurities and increase wiring resistance or cause disconnection, and thus it is necessary to remove these impurities after etching. In addition, in a fine wiring or the like, since a wiring width and a pitch between the wirings are small (narrow), it is necessary to remove the C-containing protective film 105, the oxide film 106 of the oxidized etching target material 102, and the etching residue 111 without scraping the etching target material 102 which is not altered. Further, since roughness of the side wall 125 of the etching target material 102 after the removal of the C-containing protective film 105, the oxide film 106 of the oxidized etching target material 102, and the etching residue 111 increases the wiring resistance, it is necessary to reduce the roughness and remove materials.

In the protective film and residue removing step (S6), first, the apparatus control unit 43 controls the gas supply unit 33 to supply the protective film removing gas 38 to the processing chamber 31 at a predetermined flow rate. In a state in which the protective film removing gas 38 is supplied and the inside of the processing chamber 31 reaches a predetermined pressure, the apparatus control unit 43 controls the radio frequency power supply 54 to apply the radio frequency power 53 to the radio frequency application unit 42, thereby generating plasma by the protective film removing gas 38 inside the processing chamber 31. The protective film removing gas 38 becomes the plasma and generates radicals 109 and ions 110 for removing the protective film 105 on the etching target material 102, the oxide film 106 of the oxidized etching target material 102, and the etching residue 111. The etching residue 111 can be referred to as an altered layer. As the protective film removing gas 38, for example, a mixed gas containing a H₂ gas can be used. Alternatively, a mixed gas of an H₂ gas and N₂ may be used. The C-containing protective film 105 can react with the H radicals 109 and the H ions 110 to generate CH-based reaction products to be removed. At this time, since the etching target material 102 under the protective film 105 does not react with H, the protective film 105 can be removed without scraping the etching target material 102. The oxide film 106 of the oxidized etching target material 102 can generate H₂O by the hydrogen radicals 109 and the hydrogen ions 110 to reduce the oxide film 106 of the oxidized etching target material 102. Examples of the etching residue 111 include reaction products of the C-containing protective film 105 with halogen ions and halogen radicals. Such reaction products of carbon (C) and halogen can be volatilized and removed by the hydrogen radicals 109 and the hydrogen ions 110. In this way, the processed etching target material 102 can be removed without being scraped. The main removing step S6 may be performed after the mask material 103 is removed.

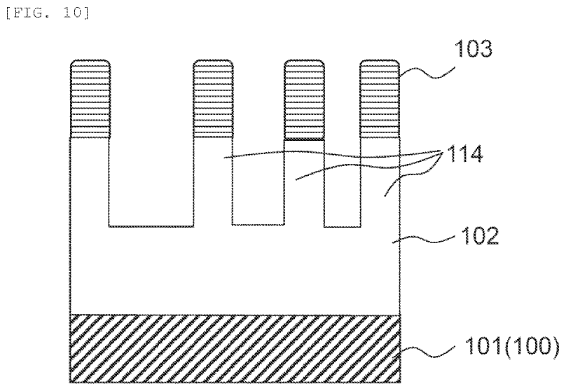

FIG. 10 shows an example of another embodiment of a pattern etched in the embodiment. As the mask pattern 103, patterns having different dimensions (intervals) in the horizontal direction are formed on the surface of the same wafer 100 (the substrate 101), and the etching target material 102 is processed with different pattern dimensions (intervals). When patterns 114 having different processing dimensions formed on the same wafer 100 are etched, the etching may be performed at different etching depths depending on the pattern dimensions. However, in the embodiment, since the oxide films 106 having the same film thickness are formed in the oxidation step (S3) and the oxide films 106 are etched in the etching step (S4) even in pattern bottom portions with different dimensions, the patterns can be processed to have the same etching depth even in the pattern bottom portions having different dimensions (intervals) in the horizontal direction.

In this way, the C-containing protective film 105 is formed on the pattern side wall 125 (S2), the C-containing protective film 105 (1052) on the pattern bottom surface (bottom portion) 120 is oxidized (S3), and the oxide film 106 of the etching target material 102 of the pattern bottom portion 120 is etched (S4). Accordingly, the etching of the pattern in the lateral direction is prevented, and the pattern can be processed in the vertical direction. In addition, the unnecessary C-containing protective film 105 attached to the pattern bottom portion 120 is oxidized and removed, and molybdenum or ruthenium which is the etching target material 102 of the pattern bottom portion 120 is oxidized, and thus uniform processing can be performed within the surface of the wafer 100. Further, after the etching is performed until reaching a desired depth, by processing with plasma containing hydrogen (step S6), the C-containing protective film 105 and the etching residue 111 on the pattern side wall 125 are removed without proceeding with the etching of molybdenum or ruthenium on the side wall 125 of the etching target material 102. Accordingly, it is possible to perform a patterning process of the etching target material 102 without causing a defect or deteriorating electrical characteristics such as wiring resistance.

In addition, in the embodiment, a case in which a shape perpendicular to the substrate 101 is processed into a pattern shape is mainly described, whereas by forming the C-containing protective film 105 on the pattern side wall 125 (S2) and oxidizing and removing the protective film 105 under the pattern side wall 125 in the oxidation processing step (S3) of oxidizing the pattern bottom portion 120, the lower portion of the pattern side wall 125 can be etched in the lateral direction to form a reverse tapered pattern.

Although the present disclosure has been specifically described based on the embodiment, the present disclosure is not limited to the embodiment, and it is needless to say that various modifications can be made without departing from the gist of the present disclosure. For example, the embodiment described above has been described in detail to facilitate understanding of the present disclosure, and the present disclosure is not necessarily limited to those including all the configurations described above. A part of the configuration of each embodiment may be added to, deleted from, or replaced with another configuration.

### REFERENCE SIGNS LIST

30: etching apparatus
31: processing chamber
32: wafer stage
33: gas supply unit
34: etching gas
35: protective film forming gas
36: film quality control gas
37: etching gas
38: protective film removing gas
41: bias power supply
42: radio frequency application unit
43: apparatus control unit
44: gas control unit
45: exhaust system control unit
46: radio frequency control unit
47: bias control unit
48: protective film forming step control unit
49: determination unit
50: database
51: storage unit
52: clock
53: radio frequency power
54: radio frequency power supply
55: bias voltage
56: control signal
57: plasma
100: wafer
101: substrate
102: etching target material
103: mask
104: SiO₂ protective film
105: C-containing protective film
106: oxide film
107: ion
108: oxygen radical
109: hydrogen radical
110: hydrogen ion
111: residue
112: dependency of etch rate on oxidation processing time when no protective film is present
113: dependency of etch rate on oxidation processing time when protective film is formed
114: patterns with different dimensions
ER1: saturated etch rate
T: oxidation time until etching is started
T_{sw}: oxygen processing time necessary for etching side wall
T_{btm}: oxygen processing time necessary for etching pattern bottom surface

1-6. (canceled)

7. A plasma processing method comprising:
a first step of forming a pattern on a molybdenum-containing film or a ruthenium-containing film using plasma generated by a mixed gas of a gas containing oxygen and a gas containing halogen;
a second step of forming, after the first step, a protective film on the pattern using plasma generated by a gas containing carbon;
a third step of oxidizing, after the second step, the molybdenum-containing film at a bottom of the pattern or ruthenium-containing film at a bottom of the pattern using plasma generated by a gas containing oxygen; and
a fourth step of etching, after the third step, the oxidized molybdenum-containing film or the oxidized ruthenium-containing film using plasma generated by a gas containing halogen,
wherein the second to fourth steps are repeated until reaching a predetermined pattern depth.

8. The plasma processing method according to claim 7, further comprising:
a fifth step of, after the fourth step, removing the protective film and an altered layer formed on a surface of the molybdenum-containing film or an altered layer formed on the ruthenium-containing film using plasma generated by a gas containing hydrogen.

9. The plasma processing method according to claim 7, wherein the gas containing halogen is a chlorine gas (Cl₂), a hydrogen bromide gas (HBr), a nitrogen trifluoride gas (NF₃), or a sulfur hexafluoride gas (SF₆).

10. The plasma processing method according to claim 7, wherein the gas containing halogen is a tetrafluoromethane gas (CF₄) or a trifluoromethane gas (CHF₃).

11. The plasma processing method according to claim 7, wherein the gas containing carbon is a methane gas (CH₄), a tetrafluoromethane gas (CF₄) or a trifluoromethane gas (CHF₃), a fluoromethane gas (CH₃F), a perfluorocyclobutane gas (C₄F₈), a carbon monoxide gas (CO) or a carbon dioxide gas (CO₂).

12. The plasma processing method according to claim 7, wherein the method further comprises, after the second step, a step of reducing roughness of the protective film using plasm generated by an argon gas (Ar), a helium gas (He), a nitrogen gas (N₂), a hydrogen gas (H₂).

13. The plasma processing method according to claim 8, wherein the method further comprises, after the second step, a step of reducing roughness of the protective film using plasm generated by an argon gas (Ar), a helium gas (He), a nitrogen gas (N₂), a hydrogen gas (H₂).
